(19) United States
(12) Patent Application Publication
(10) Pub. No.: US 2025/0112190 A1
(43) Pub. Date: Apr. 3, 2025

(54) SELF-DIFFUSING LIQUID METAL INTERCONNECT ARCHITECTURES ENABLING SNAP-ON ROOM TEMPERATURE ASSEMBLY

(71) Applicant: Intel Corporation, Santa Clara, CA (US)

(72) Inventors: Xiao Lu, Chandler, AZ (US); Sangeon Lee, Chandler, AZ (US); Jiaqi Wu, Chandler, AZ (US); Tingting Gao, Chandler, AZ (US); Matthew T. Magnavita, Chandler, AZ (US); Ravindranath V. Mahajan, Chandler, AZ (US)

(73) Assignee: Intel Corporation, Santa Clara, CA (US)

(21) Appl. No.: 18/477,966

(22) Filed: Sep. 29, 2023

(51) Int. Cl. H01L 23/00

(52) U.S. Cl. CPC H01L 24/14; H01L 24/13; H01L 24/16; H01L 24/81; H01L 2224/13011; H01L 2224/14517; H01L 2224/16227; H01L 2224/81007

(57) ABSTRACT

In one embodiment, an integrated circuit device includes a substrate and a component coupled to the substrate. The substrate includes first reservoirs comprising Gallium-based liquid metal (LM), second reservoirs, first channels between the first reservoirs, and second channels between the second reservoirs and respective first reservoirs. The component includes circuitry and conductive contacts connected to the circuitry. Each contact defines a cavity and a portion of each conductive contact is within a respective first reservoir of the substrate such that it is in contact with the LM in the first reservoir. The component further includes dielectric lines between the conductive contacts, and each dielectric line is at least partially within a respective first channel of the substrate.

### BACKGROUND

Liquid metal (LM) interconnect architectures may utilize Gallium (Ga) or Ga-based alloy liquid metals to provide separable and reusable interconnections for integrated circuit devices, e.g., in lieu of traditional solder-based interconnection technologies (e.g., ball grid arrays) that are substantially permanent in their current implementations.

### BRIEF DESCRIPTION OF THE DRAWINGS

FIGS. 1A-1B illustrate an example integrated circuit component and substrate incorporating a LM interconnect in accordance with embodiments of the present disclosure.

FIGS. 2A-2B illustrate side and top views, respectively, of an example process for filling reservoirs of a substrate with LM in accordance with embodiments of the present disclosure.

FIGS. 3A-3B illustrate side and top views, respectively, of an example process for attaching an integrated circuit component to a substrate in accordance with embodiments of the present disclosure.

FIG. 4 illustrates the capillary process by which the contacts of the component cause LM within the reservoirs of the substrate to fill the cavities defined by the contacts.

FIG. 5 illustrates another example embodiment of a contact that may be implemented in embodiments of the present disclosure.

FIGS. 6-7 illustrate example systems incorporating LM interconnects in accordance with embodiments of the present disclosure.

FIGS. 8A-8C illustrate effects of a slip layer material that can be incorporated into embodiments of the present disclosure.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Embodiments herein include integrated circuit device assemblies that utilize liquid metal (LM) interconnects, e.g., between an integrated circuit die and an integrated circuit package substrate. In typical assembly processes for integrated circuit device assemblies, there are multiple thermal exposure operations that are performed, e.g., reflow oven, thermal compression bonding, baking, etc. In some instances, e.g., with packages having thermally sensitive components (e.g., optical devices), it may be desirable to reduce the number of thermal exposure operations. Indeed, room temperature assembly may be preferred, if possible.

Aspects of the present disclosure provide techniques for forming a liquid metal-based interconnect between integrated circuit device assembly components at or near room temperature, utilizing the fluidic nature of the LM material. With embodiments herein, self-diffusion channels in a component (e.g., a substrate, such as an integrated circuit package substrate) allow LM to flow to interconnect points of the component based on capillary force. Thus, LM material only need be dispensed to a few reservoirs at particular locations of the component, with the full interconnect network being formed by a self-diffusion process. Thereafter, an attachment process can be used to bond the component to another component of the assembly. In the attachment process, the interconnect points between the components are formed and the channels in the first component to diffuse the LM are electrically disconnected (e.g., via material depletion and/or dielectric layer insulation as described below).

In some embodiments, a slip layer material may be used in the interconnect network to remove an oxide surface from the LM to further facilitate the self-diffusion process. The slip layer material may weaken the critical yield stress of the LM, and can create a slip layer between the LM and the walls of the micro-channels in the component to enable continuous capillary wetting. The inclusion of the slip layer material can address one of the major practical issues to use gallium-based LM for self-diffusion process, i.e., the oxide formation when exposed to elements such as air. In addition, the presence of the slip layer material provides a way to avoid toxic mercury (Hg), which readily fills microchannels without any pre- or post-treatment while being toxic and forming unstable structures.

Current attachment techniques include squeegee printing, template assisted spray coating, contact dispensing, and electrodeposition. Squeegee printing may refer to a mass printing method realized by pressing a LM through a patterned stencil with a squeegee. Template assisted spray coating may refer to a template-assisted method used in conjunction with traditional methods such as spray coating. Contact dispensing may refer to a dispensing of LM only where it is needed. Electrodeposition uses photolithography equipment to electrodeposit liquid metal to a target substrate. However, there several disadvantages of these conventional printing techniques. For instance, squeegee printing is a material consuming process and likely causes insufficient filling of reservoirs in a component. It can generate more waste because it must start with complete surface coverage and then removal of material to form the desired structures. Template assisted spray coating incurs high costs due to its complex manufacturing process. Further, it has a short service life as compared with other techniques. Contact dispensing may have issues with scalability into high pin count applications, since contacts are dispensed one at a time. Finally, electrodeposition requires expensive photolithography equipment (e.g., high cost of masks) and complicated chemical processing steps.

Aspects of the present disclosure can provide a number of various advantages over these or other existing techniques. For example, the techniques described herein are relatively simple when compared with existing techniques, requiring minimal energy and providing rapid and reversible control of interfacial tension independent of the properties of the substrate. In addition, due to the nature of the self-diffusion process used, an interconnect matrix can be designed with higher pin counts and/or finer pitch, without corresponding increases in processing time or costs. Such scalability is a distinctive advantage over current manufacturing process techniques. In addition, the interconnect formation techniques described herein can be applied to various late-attach applications without the need for a traditional socket/interposer, e.g., memory attachment to an integrated circuit package or a package being attached to a system board/motherboard.

Other advantages can include: capillary imbibition-induced, spontaneous, and selective wetting characteristics on any surface with micro-scale topographical features, providing highly precise and repeatable deposits of LM, almost independent of the substrate topographical variance; reconfigurable shapes/contacts depending on the wettability of LM used; less LM material is needed to make a whole interconnect circuit (e.g., only a few droplets may be required), potentially bringing high throughput; uniform coating and patterning of the LM over large areas can be achieved without an external force or complex processing; and the wetting of the LM on the surface is thermodynamically favorable, which makes the resulting LM stable.

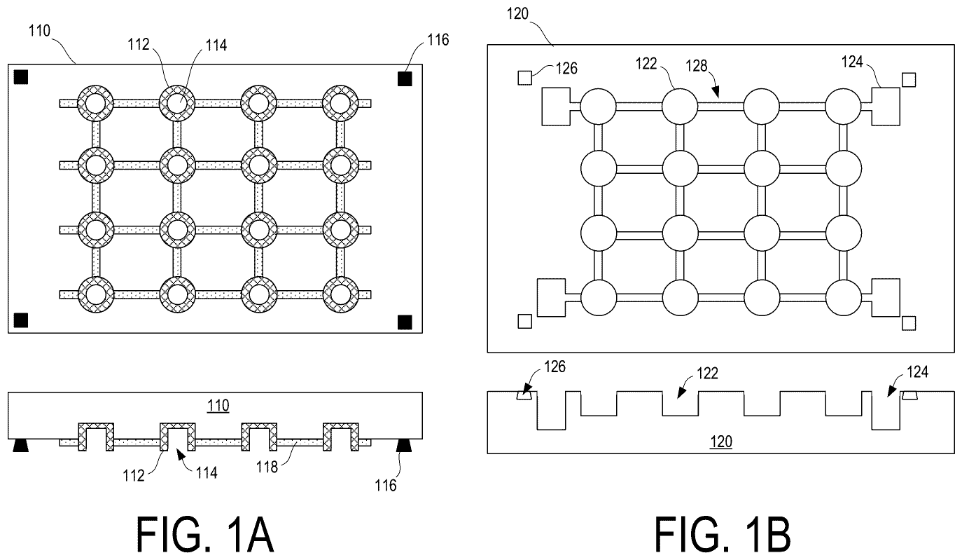

FIGS. 1A-1B illustrate an example integrated circuit component 110 and substrate 120 incorporating a LM interconnect in accordance with embodiments of the present disclosure. The example component 110 includes a substrate with a number of conductive contacts 112 that define cavities 114 as shown. The contacts 112 may be electrically connected with circuitry, including traces, vias, or other electrical components, within or on the substrate of the component 110. In the example shown, the contacts 112 slightly protrude from the bottom surface of the component 110 and the cavities 114 are slightly recessed into the body of the component 110. Further, in the example shown, the contacts 112 are generally cylindrical in shape (i.e., circular cross-section as shown in the top view); however, other embodiments may implement contacts 112 that are shaped in a different manner than shown (e.g., with a rectangular, oval, or other cross-section). The contacts 112 may include any suitable electrically conductive material, such as a metal (e.g., Nickel). In some embodiments, the contacts 112 may be fabricated on the component 110 by a plating process.

The component 110 further includes dielectric lines 118 protruding from the bottom surface, and arranged between the contacts 112 (to correspond with the network of channels 128 described below). The dielectric lines 118 may have pressure sensitive adhesion properties in certain embodiments. The dielectric lines 118 may include certain ceramics, e.g., alumina (Al₂O₃), silicon dioxide (SiO₂), silicon nitride (Si₃N₄), fused silica, or glass substrates, e.g., borosilicate glass, which can be advantageous due to their adhesive characteristics (e.g., to aid in bonding). The component also includes a set of mechanical bonding structures 116 that protrude from the bottom surface of the component. The example mechanical bonding structures 116 shown are trapezoidal in shape; however, the mechanical bonding structures 116 can be formed in any suitable manner or shape. In some embodiments, the mechanical bonding structures 116 can be formed of the same dielectric material as the lines 118.

The substrate 120 defines a number of contact reservoirs 122 (defined by its upper surface), which correspond to the arrangement of the contacts 112 on the component 110. In addition, the substrate 120 defines a set of filling reservoirs 124 (also defined by the upper surface of the substrate) with a network of channels 128 (also defined by the upper surface of the substrate) connecting each of the filling reservoirs 124 with the contact reservoirs 122. The channels 128 may thus provide for self-diffusion channels for LM deposited in the filling reservoirs 124 to flow into the contact reservoirs 122, as is described further below.

The substrate 120 further defines a set of cavities 126 for receiving the mechanical bonding structures 116 of the component 110 when the component 110 and substrate 120 are bonded together. The cavities 126 may substantially match the shape of the mechanical bonding structures 116, as shown. In the example shown, the mechanical bonding structures 116 are designed such that they “snap-in” to the cavities 126 when the component 110 and the substrate 120 are pushed together. Other embodiments may utilize other types of bonding structures than those shown.

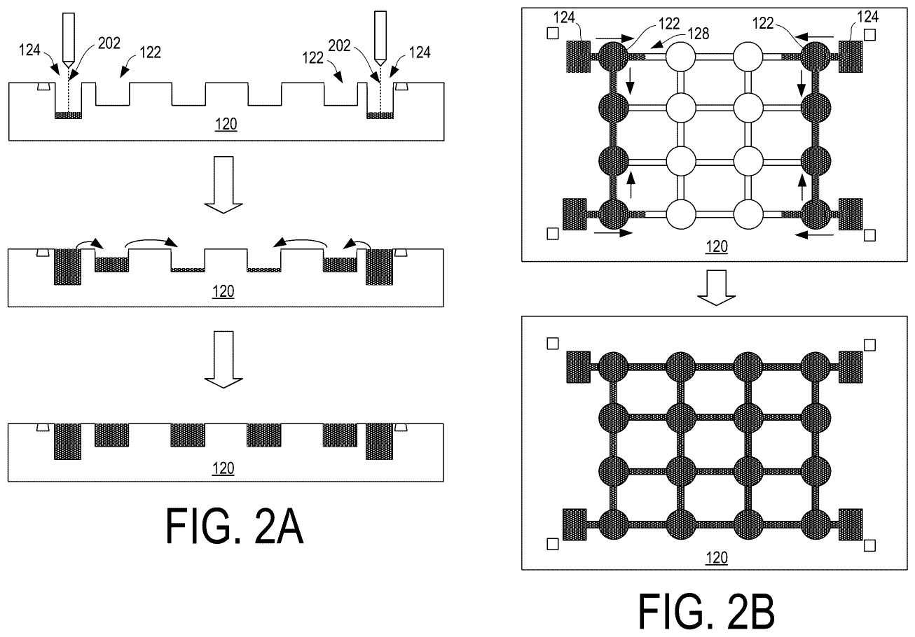

FIGS. 2A-2B illustrate side and top views, respectively, of an example process for filling reservoirs of a substrate with LM in accordance with embodiments of the present disclosure. As shown, in embodiments herein, LM 202 may be deposited into the filling reservoirs 124 of the substrate 120. As the filling reservoirs 124 begin to become full, the LM 202 may flow via capillary force through the channels 128 and into the contact reservoirs 122. The flow/self-diffusion of the LM 202 may be aided, in certain embodiments, by depositing a slip layer material within the channels 128 to prevent oxidation of the LM 202, as described further below. Once the reservoirs 122 and the channels 128 are filled with LM 202, the component 110 can be attached.

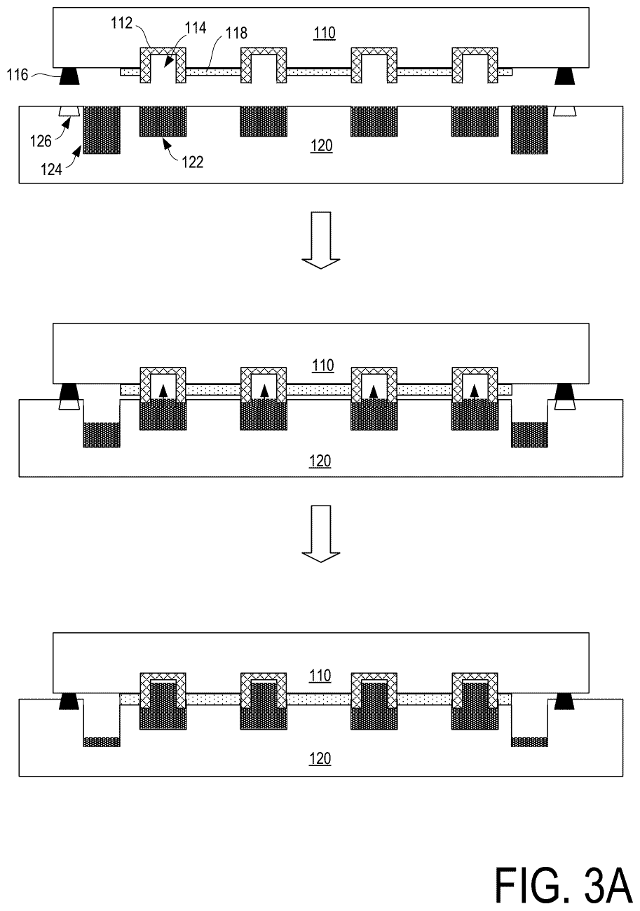

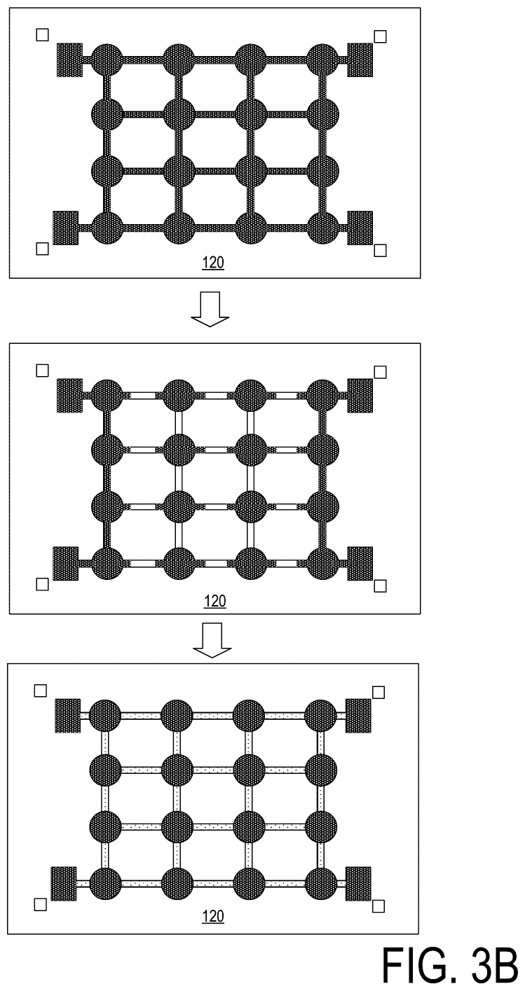

FIGS. 3A-3B illustrate side and top views, respectively, of an example process for attaching an integrated circuit component to a substrate in accordance with embodiments of the present disclosure. As shown in FIG. 3A, as the component 110 is pressed onto the substrate 120, the contacts 112 activate a capillary action and the LM within the contact reservoirs 122 flows upward into the cavities 114 formed by the contacts 112, causing the LM and the contacts 112 to be in good physical (and thus, electrical) contact with one another. Further, as shown in FIG. 3B, as the LM fills into the cavities 114, the LM depletes from the channels 128 of the substrate 120, causing a disconnection in the LM in the channels (e.g., as shown in the middle illustration of FIG. 3B). In addition, as the component 110 and substrate 120 are further pressed together, the dielectric lines 118 begin to insert into the channels 128 of the substrate 120, causing the LM to further deplete into the cavities 114 and further causing electrical isolation of the LM in the reservoirs 122/cavities 114. In embodiments that implement dielectric with pressure sensitive adhesion properties, the bonding force promotes adhesion between the dielectric lines 118 and the substrate 120 to form a permanent or semi-permanent bond. Further, as shown, the mechanical bonding structures 116 of the component 110 are inserted into the cavities 126 of the substrate 120 to further secure the bond between the two.

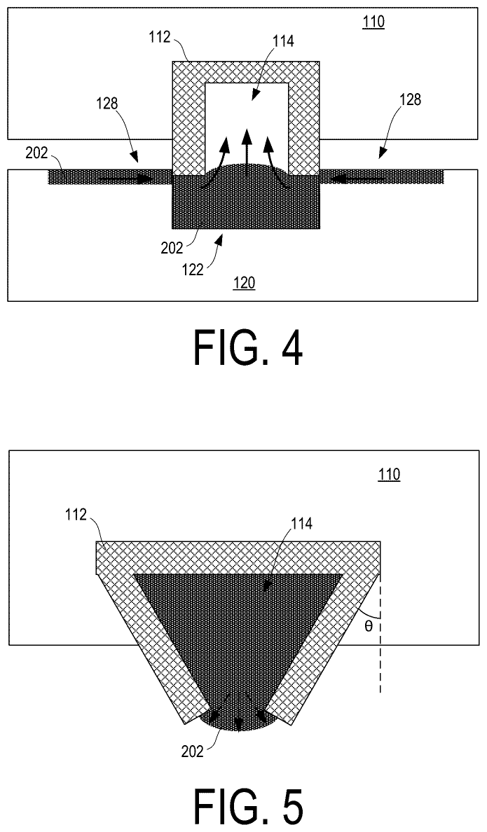

FIG. 4 illustrates the capillary process by which the contacts of the component cause LM within the reservoirs of the substrate to fill the cavities defined by the contacts. As demonstrated in FIG. 4, when the component 110 and the substrate 120 make physical contact, the LM moves into the cavity 114 formed by the contact 112 due to higher surface energy. Where a slip layer is used, the slip layer creates a LM-philic layer in the channels 128, resulting in lower surface energy and helping to make a smooth transfer of the LM into the cavity 114. In other words, the cavity 114 formed by the contact 112 structure effectively sucks the LM 202 from the reservoir 122, and the LM in the diffusion channels 128 begin to separate/disconnect (e.g., as shown in the middle illustration of FIG. 3B) due to the movement of LM into the cavities 114. This spontaneous transfer process ultimately depletes the LM 202 from the channels 128 of the substrate 120.

FIG. 5 illustrates an alternate example embodiment of a contact that may be implemented in embodiments of the present disclosure. In particular, FIG. 5 illustrates an alternate form of the contacts 112, in which the walls of the contact that protrude from the component 110 are at an angle θ with respect to the upper portion of the contact 112 within the component 110. This angled formation of the contact 112 may serve to increase the suction of the LM 202 up into the cavity 114, and also to further ensure that the LM 202 remains inside the cavity 114 after transfer.

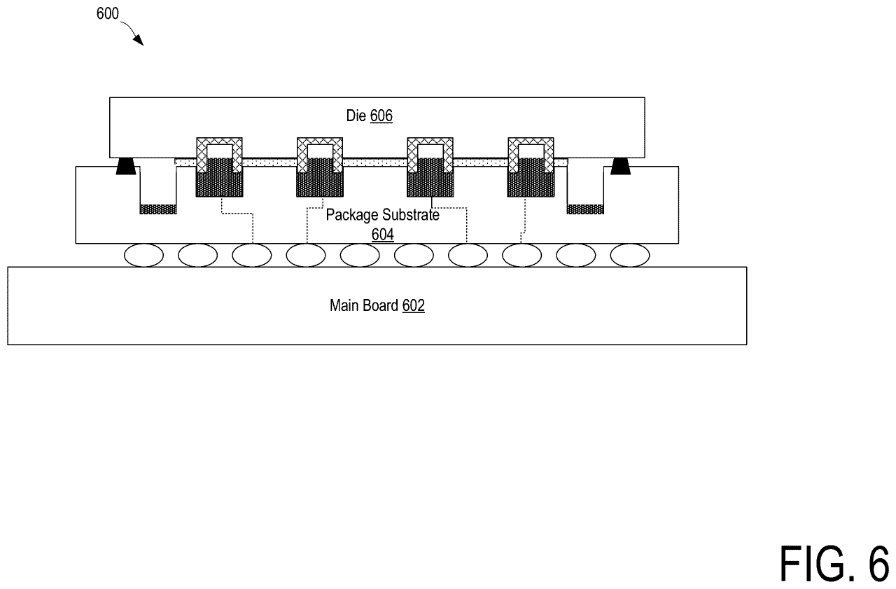

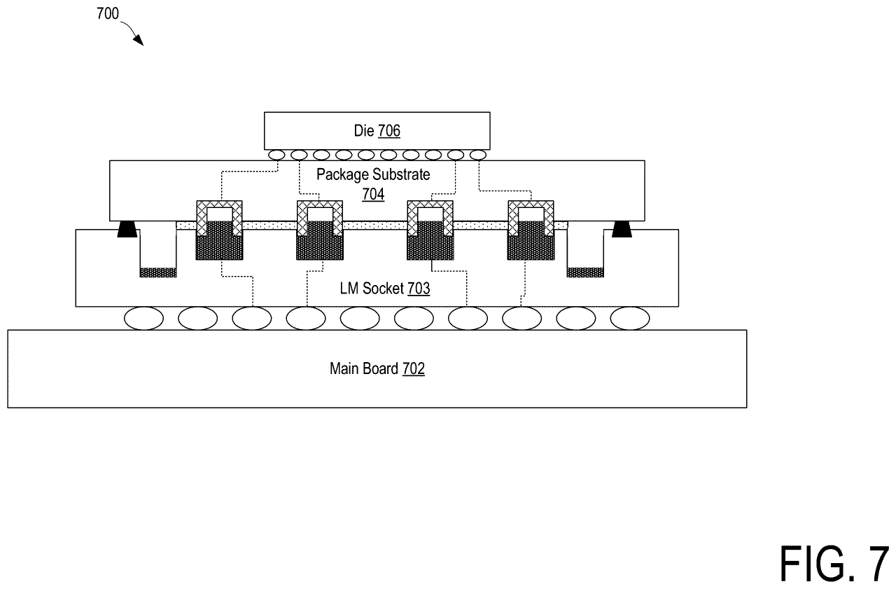

FIGS. 6-7 illustrate example systems 600, 700 incorporating LM interconnects in accordance with embodiments of the present disclosure. In FIG. 6, the example system 600 includes a package substrate 604 coupled to the main board 602, and a die 606 coupled to the package substrate 604. The package substrate 604 includes features of the substrate 120 described above, while the die 606 includes features of the component 110 described above. In FIG. 7, the example system 700 includes an LM socket 703 coupled to the main board 702, with a package substrate 704 coupled to the LM socket and a die 706 coupled to the package substrate 704. The LM socket 703 includes features of the substrate 120 described above, while the package substrate includes features of the component 110 described above.

Each example includes a main board 602, 702, which may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the main board. In other embodiments, the main board may be or include a non-PCB substrate.

The dies 606, 706 may be an integrated circuit die comprising one or more computing system components, such as one or more processor units (e.g., system-on-a-chip (SoC), processor core, graphics processor unit (GPU), accelerator, chipset processor), I/O controller, memory, or network interface controller. In some embodiments, the dies 606, 706 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the dies 606, 706 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units.

In embodiments where an integrated circuit component comprises multiple integrated circuit dies, interconnections between dies can be provided by the package substrate 604, 704, one or more silicon interposers, one or more silicon bridges embedded in the package substrate 604, 704 (such as Intel® embedded multi-die interconnect bridges (EMIBs)), or combinations thereof. The package substrates 604, 704 may further provide electrical interconnections between the dies 606, 706 and the main boards 602, 702 (e.g., as shown by the dotted lines).

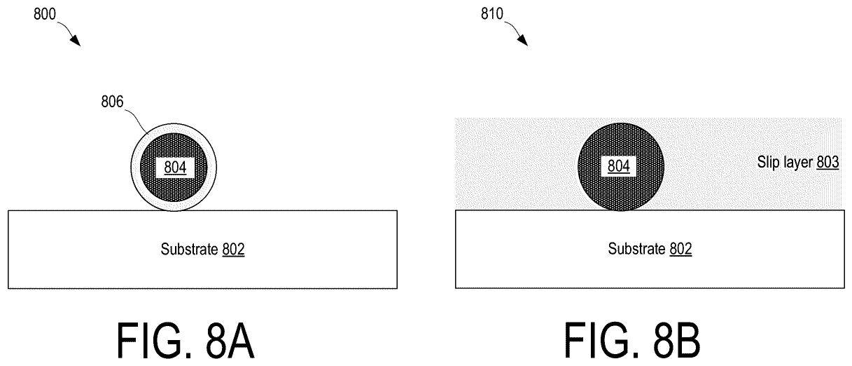

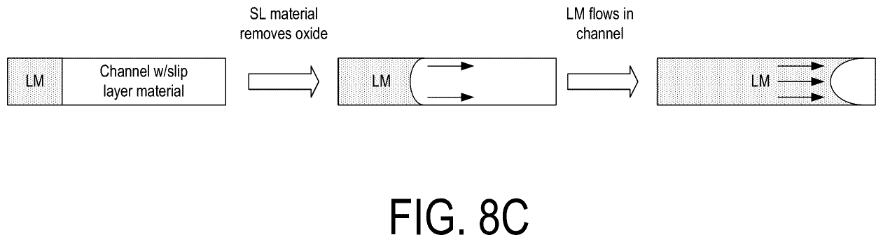

FIGS. 8A-8C illustrate effects of a slip layer material that can be incorporated into embodiments of the present disclosure. In particular, FIG. 8A illustrates an example LM 804 on a substrate 802 without a slip layer material, while FIG. 8B illustrates the LM 804 on the substrate 802 that includes a slip layer material 803 according to embodiments herein. As shown in FIG. 8A, the LM 804 can maintain structural stability at room temperature, i.e., does not spontaneously flow or retract from the channel due to a thin “skin” 806 that is formed on the surface of the LM 804 when the LM 804 is exposed to air. This thin skin 806 mostly comprises oxides from the Gallium particles and forms spontaneously and nearly instantaneously upon exposure to atmospheric oxygen. The surface oxide is responsible for the rigid skin 806, and the presence of a rapidly forming oxide skin on the surface of the LM causes it to stick to many surfaces, which limits the ability to easily reconfigure its shape on demand. Thus, under ambient conditions, e.g., those without any slip layer material, it may be difficult to fill the LM from the filling reservoirs of a substrate (e.g., 126 of FIG. 1B) into the channels (e.g., 128) of the substrate and into the contact reservoirs (e.g., 122) because of the high cohesion force and thin skin.

However, embodiments herein may include a slip layer material 803 in the reservoirs (e.g., 122, 126) and/or the channels (e.g., 128) of a substrate to prevent the LM 804 from forming the skin 806. With this inclusion, the surface oxide skin (e.g., 806) on a LM can be removed in situ and behaves like a surfactant that can significantly lower its interfacial tension from, e.g., ˜500 mJ/m² to near zero. Examples slip layer materials that can be used include various oils (e.g., mineral oil, silicone oil, etc.), solvents (methanol, ethanol, isopropyl alcohol, etc.), bases (sodium hydroxide, potassium hydroxide, calcium carbonate, etc.), or acids (hydrogen chloride, sulfuric, nitric acid, etc.). These materials can provide an interfacial slip layer between the LM and the substrate or other surfaces, which allows the LM to flow smoothly from the reservoirs into the channels without oxidizing and sticking.

FIG. 8A illustrates how the LM 804, when dispensed into a dry capillary on the substrate 802, forms the oxide skin 806 spontaneously and adheres to the capillary wall. The LM thus may not be able to flow out of the capillary under the ambient conditions. In contrast, as shown in FIG. 8B, when the capillary on the substrate 802 is filled with a solution, the oxide skin may not form on the LM 804 (or may be thin and mechanically weak). Thus, the LM 804 does not adhere to the capillary, allowing the LM 804 to flow smoothly through the capillary without sticking.

FIG. 8C illustrates an example model of the LM 804 in a small channel, and shows how the channel is spontaneously filled with the LM when the oxide is removed by the slip layer material 803. Because of the existence of a slip layer material and low interfacial energy at the air/LM interface in the channel, the LM spontaneously diffuses through the channel. Both the slip layer material and the low interfacial energy are used to transport the LM through the self-diffusive channel.

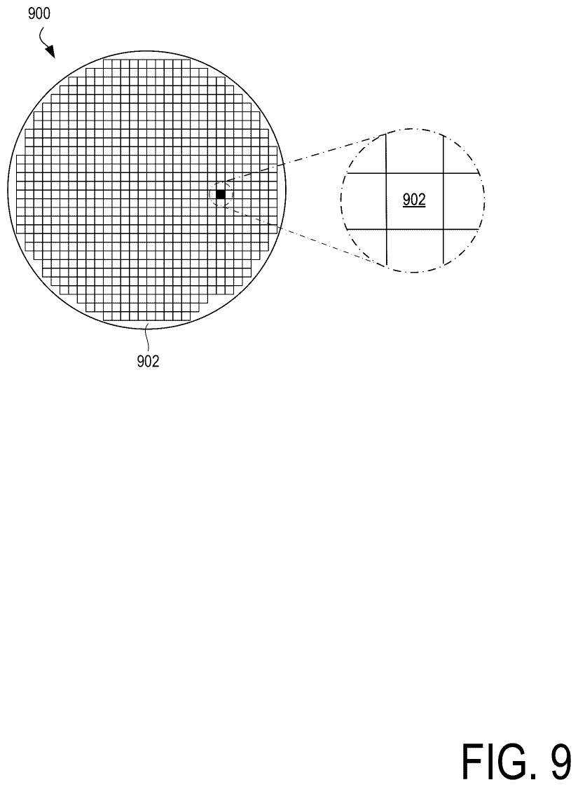

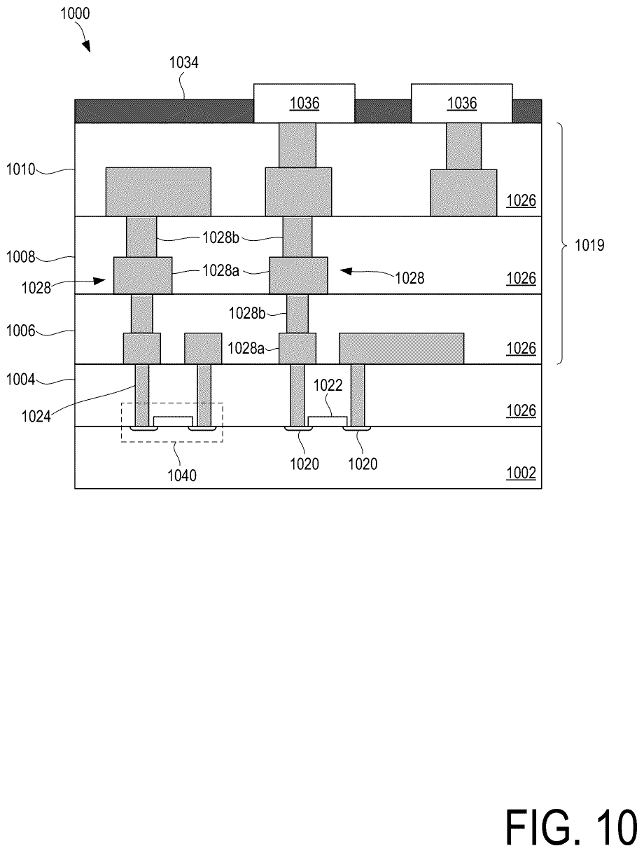

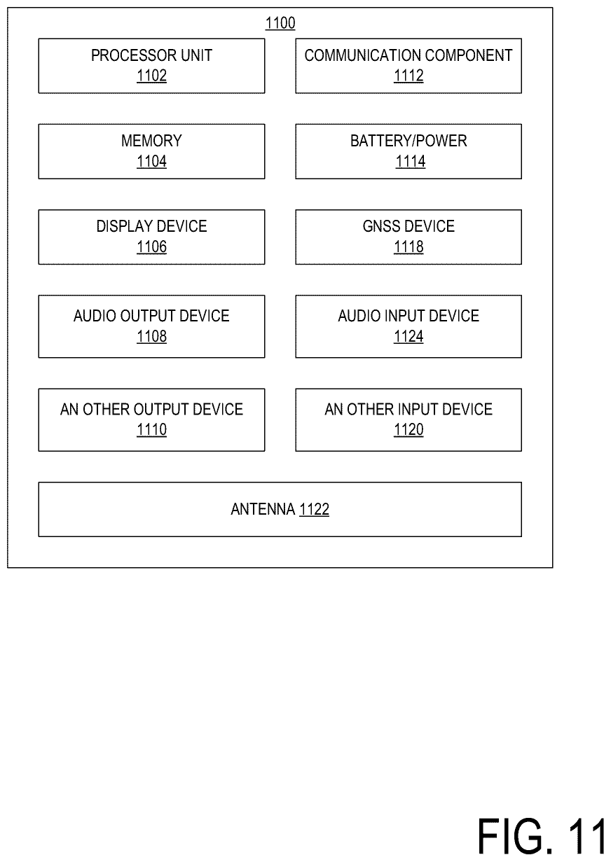

FIG. 9 is a top view of a wafer 900 and dies 902 that may incorporate any of the embodiments disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors (e.g., some of the transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1102 of FIG. 11) or other logic that is configured to store information in the memory devices or execute instructions stored in the memory array.

FIG. 10 is a cross-sectional side view of an integrated circuit device 1000 that may be included in any of the embodiments disclosed herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page from the perspective of FIG. 10. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board or a package substrate, e.g., 112). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 11 is a block diagram of an example electrical device 1100 that may include one or more of the embodiments disclosed herein. For example, any suitable ones of the components of the electrical device 1100 may include one or more of assemblies 100, integrated circuit devices 1000, or integrated circuit dies 902 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include another output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include another input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data.

In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising a substrate comprising circuitry; conductive contacts connected to the circuitry, each contact defining a cavity at least partially within the substrate, a portion of each conductive contact protruding from an exterior surface of the substrate; and dielectric lines between respective pairs of the conductive contacts, the dielectric lines protruding from the exterior surface of the substrate.

Example 2 includes the subject matter of Example 1, further comprising mechanical bonding structures protruding from the exterior surface of the substrate.

Example 3 includes the subject matter of Example 2, wherein the mechanical bonding structures are between the conductive conducts and outer edges of the substrate.

Example 4 includes the subject matter of any one of Examples 1-3, wherein the mechanical bonding structures are trapezoidal in shape.

Example 5 includes the subject matter of any one of Examples 1-4, wherein the conductive contacts have circular cross-sections.

Example 6 includes the subject matter of any one of Examples 1-5, wherein the conductive contacts protrude from the exterior surface of the surface at a 90 degree angle.

Example 7 includes the subject matter of any one of Examples 1-5, wherein the conductive contacts protrude from the exterior surface of the surface at an angle less than 90 degrees.

Example 8 is an integrated circuit device comprising: a substrate comprising: first reservoirs comprising Gallium-based liquid metal (LM); second reservoirs; first channels, each first channel connecting a respective pair of first reservoirs; and second channels, each second channel between a second reservoir and a first reservoir; and a component coupled to the substrate, the component comprising: circuitry; conductive contacts connected to the circuitry, each contact defining a cavity, a portion of each conductive contact within a respective first reservoir of the substrate and in contact with the LM of the first reservoir; and dielectric lines between the conductive contacts, each dielectric line at least partially within a respective first channel of the substrate.

Example 9 includes the subject matter of Example 8, wherein the component further comprises mechanical bonding structures and the substrate further comprises cavities, the mechanical bonding structures within the cavities of the substrate.

Example 10 includes the subject matter of Example 8 or 9, further comprising a liquid in at least a portion of the first channels.

Example 11 includes the subject matter of Example 10, wherein the liquid comprises one of mineral oil, silicone oil, methanol, ethanol, isopropyl alcohol, sodium hydroxide, potassium hydroxide, calcium carbonate, hydrogen chloride, sulfuric acid, and nitric acid.

Example 12 includes the subject matter of any one of Examples 8-11, wherein the conductive contacts protrude from the component at an angle less than 90 degrees with respect to a surface of the component facing the substrate.

Example 13 includes the subject matter of any one of Examples 8-12, wherein the component is an integrated circuit die and the substrate comprises interconnections for the circuitry of the integrated circuit die.

Example 14 includes the subject matter of any one of Examples 8-12, wherein the component is a package substrate with an integrated circuit die coupled thereto and the substrate is a socket comprising interconnections for the circuitry of the integrated circuit die.

Example 15 includes the subject matter of any one of Examples 8-14, further comprising a circuit board coupled to the substrate.

Example 16 is a method comprising: dispensing a Gallium-based liquid metal (LM) into first reservoirs of a substrate, wherein dispensing the LM causes the LM to flow into second reservoirs of the substrate via channels in the substrate; and bonding an integrated circuit die to the substrate, wherein bonding the integrated circuit die comprises inserting conductive contacts of the integrated circuit die at least partially within the second reservoirs of the substrate to cause the LM within the second reservoirs to become in contact with the conductive contacts.

Example 17 includes the subject matter of Example 16, further comprising dispensing a liquid slip layer material into the channels.

Example 18 includes the subject matter of Example 17, wherein the liquid slip layer material comprises one of mineral oil, silicone oil, methanol, ethanol, isopropyl alcohol, sodium hydroxide, potassium hydroxide, calcium carbonate, hydrogen chloride, sulfuric acid, and nitric acid.

Example 19 includes the subject matter of any one of Examples 16-18, wherein bonding the integrated circuit die to the substrate further comprises inserting dielectric lines of the integrated circuit die into channels of the substrate between the conductive contacts.

Example 20 includes the subject matter of any one of Examples 16-19, wherein bonding the integrated circuit die to the substrate further comprises inserting mechanical bonding structures of the integrated circuit die into cavities of the substrate.

Example 21 is an apparatus comprising: a substrate comprising circuitry; a first conductive contact connected to the circuitry and at least partially protruding from an exterior surface of the substrate, the first conductive contact defining a cavity at least partially within the substrate; a first conductive contact connected to the circuitry and at least partially protruding from the exterior surface of the substrate, the first conductive contact defining a cavity at least partially within the substrate; and a dielectric line in contact with the first conductive contact and the second conductive contact, the dielectric line protruding from the exterior surface of the substrate.

Example 22 includes the subject matter of Example 21, further comprising mechanical bonding structures protruding from the exterior surface of the substrate.

Example 23 includes the subject matter of Example 22, wherein the mechanical bonding structures are between the conductive contacts and outer edges of the substrate.

Example 24 includes the subject matter of Example 22, wherein the mechanical bonding structures are trapezoidal in shape.

Example 25 includes the subject matter of Example 21, wherein the conductive contacts have circular cross-sections.

Example 26 includes the subject matter of Example 21, wherein the conductive contacts protrude from the exterior surface of the substrate at a 90 degree angle.

Example 27 includes the subject matter of Example 21, wherein the conductive contacts protrude from the exterior surface of the substrate at an angle less than 90 degrees.

Example 28 is a device or apparatus formed by any one of Examples 16-20.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a substrate comprising circuitry;
conductive contacts connected to the circuitry, each contact defining a cavity at least partially within the substrate, a portion of each conductive contact protruding from an exterior surface of the substrate; and
dielectric lines between respective pairs of the conductive contacts, the dielectric lines protruding from the exterior surface of the substrate.

2. The apparatus of claim 1, further comprising mechanical bonding structures protruding from the exterior surface of the substrate.

3. The apparatus of claim 2, wherein the mechanical bonding structures are between the conductive contacts and outer edges of the substrate.

4. The apparatus of claim 2, wherein the mechanical bonding structures are trapezoidal in shape.

5. The apparatus of claim 1, wherein the conductive contacts have circular cross-sections.

6. The apparatus of claim 1, wherein the conductive contacts protrude from the exterior surface of the substrate at a 90 degree angle.

7. The apparatus of claim 1, wherein the conductive contacts protrude from the exterior surface of the substrate at an angle less than 90 degrees.

8. An integrated circuit device comprising:
a substrate comprising:
first reservoirs comprising Gallium-based liquid metal (LM);
second reservoirs;
first channels, each first channel connecting a respective pair of first reservoirs; and
second channels, each second channel between a second reservoir and a first reservoir; and
a component coupled to the substrate, the component comprising:
circuitry;
conductive contacts connected to the circuitry, each contact defining a cavity, a portion of each conductive contact within a respective first reservoir of the substrate and in contact with the LM of the first reservoir; and
dielectric lines between the conductive contacts, each dielectric line at least partially within a respective first channel of the substrate.

9. The integrated circuit device of claim 8, wherein the component further comprises mechanical bonding structures and the substrate further comprises cavities, the mechanical bonding structures within the cavities of the substrate.

10. The integrated circuit device of claim 8, further comprising a liquid in at least a portion of the first channels.

11. The integrated circuit device of claim 10, wherein the liquid comprises one of mineral oil, silicone oil, methanol, ethanol, isopropyl alcohol, sodium hydroxide, potassium hydroxide, calcium carbonate, hydrogen chloride, sulfuric acid, and nitric acid.

12. The integrated circuit device of claim 8, wherein the conductive contacts protrude from the component at an angle less than 90 degrees with respect to a surface of the component facing the substrate.

13. The integrated circuit device of claim 8, wherein the component is an integrated circuit die and the substrate comprises interconnections for the circuitry of the integrated circuit die.

14. The integrated circuit device of claim 8, wherein the component is a package substrate with an integrated circuit die coupled thereto and the substrate is a socket comprising interconnections for the circuitry of the integrated circuit die.

15. The integrated circuit device of claim 8, further comprising a circuit board coupled to the substrate.

16. A method comprising:
dispensing a Gallium-based liquid metal (LM) into first reservoirs of a substrate, wherein dispensing the LM causes the LM to flow into second reservoirs of the substrate via channels in the substrate; and
bonding an integrated circuit die to the substrate, wherein bonding the integrated circuit die comprises inserting conductive contacts of the integrated circuit die at least partially within the second reservoirs of the substrate to cause the LM within the second reservoirs to become in contact with the conductive contacts.

17. The method of claim 16, further comprising dispensing a liquid slip layer material into the channels.

18. The method of claim 17, wherein the liquid slip layer material comprises one of mineral oil, silicone oil, methanol, ethanol, isopropyl alcohol, sodium hydroxide, potassium hydroxide, calcium carbonate, hydrogen chloride, sulfuric acid, and nitric acid.

19. The method of claim 16, wherein bonding the integrated circuit die to the substrate further comprises inserting dielectric lines of the integrated circuit die into channels of the substrate between the conductive contacts.

20. The method of claim 16, wherein bonding the integrated circuit die to the substrate further comprises inserting mechanical bonding structures of the integrated circuit die into cavities of the substrate.
